(19) United States
(12) Patent Application Publication
(10) Pub. No.: US 2005/0242416 A1
(43) Pub. Date: Nov. 3, 2005

(54) LOW-CAPACITANCE BONDING PAD FOR SEMICONDUCTOR DEVICE

(75) Inventor: Shiao-Shien Chen, Hsin-Chu City (TW)

Correspondence Address: SQUIRE, SANDERS & DEMPSEY L.L.P, 600 HANSEN WAY, PALO ALTO, CA, 94304-1043, US

(73) Assignee: United Microelectronics Corp., Hsin-Chu City (TW)

(21) Appl. No.: 10/709,366

(22) Filed: Apr. 29, 2004

(51) Int. Cl. H01L 23/62

(52) U.S. Cl. 257/665

(57) ABSTRACT

A low capacitance semiconductor device is provided. The low capacitance semiconductor device comprises a triple well structure in the substrate, and a bonding pad structure on the substrate, wherein the substrate having a doped region of a second conductive type, a first well region of first conductive type, and a second well region of second conductive type. There is a first junction capacitance between the diffusion region and the first well region, a second junction capacitance between the first well region and the second well region, and a third capacitance between the second well region and the substrate. The first junction capacitance, second junction capacitance, the third junction capacitance and the total equivalent capacitance are coupled in series, such that the total parasitic capacitance is effectively reduced.

### BACKGROUND OF THE INVENTION

1. Field of the Invention

The present invention generally relates to a semiconductor device. More particularly, the present invention relate to a bonding pad with low capacitance for a semiconductor device.

2. Description of the Prior Art

Trends for electrical products are light, short, small, and thin. Usually, the chip manufacturing technology and the packaging technology are rapidly developed to meet these trends. However, due to a limitation of bonding machines, a size of a bonding pad for a semiconductor device is not reduced as well as a line width of a chip is greatly reduced. Because the size of the bonding pad is insufficiently small, an area of a substrate overlapped by the bonding pad is large. As a result, a parasitic capacitance of the bonding pad remains high. Additionally, a peel-off effect often occurs while forming the bonding wire, so that bonding reliability is decreased.

The large input capacitance from the bonding pad and input ESD (electrostatic discharge) protection devices often limits the frequency performance I/O signals in high-speed integrated circuits such as the DRDRAM or RF IC. Although the progress of deep-submicron CMOS technology enables the dimension of integrated circuits dramatically shrunk, the dimension of bonding pad is still not reduced as well due to the limitation of bonding machines. The area of substrate overlapped by the bonding pad is sizeable in the whole chip area, which results in a large parasitic capacitance to degrade the operating speed of integrated circuits or to require large chip area to construct powerful driver circuits.

Moreover, the input pad must be drawn with the on-chip ESD protection devices to protect the internal circuits against ESD damages. To sustain a high ESD robustness, the ESD protection devices often have larger device dimensions. Therefore, the ESD protection devices contribute large parasitic junction capacitance to the input pad.

As illustrate in FIG. 1, shows a semiconductor device has a bonding pad structure on the substrate. The semiconductor device includes a dielectric layer 110 on the substrate 100. A bonding pad structure 200 is on the dielectric layer 110. The bonding pad structure 200 is constructed by a multiple metal layers 210, 220, 230, and a top metal layer 240. Also, the multiple metal layers 210, 220, 230 are buried deeply in multiple dielectric layers 212, 222, and 232. In addition, each of multiple metal layers adjacent to metal layer by plurality of via plugs 214, 224, 234 within the multiple dielectric layer 212, 222, and 232.

To avoid the peel-off effect that occurs on the bonding pad structure 200, the bonding pad structure 200 are constructed by planar multiple metal layers. Several forms and materials used to increase the adhesion of the metal layers on the dielectric layers during wire bonding. Although the peel-off effect on the bonding pad structure 200 is freer while the more connected metal layers are used, the more parasitic capacitance is induced because of the metal layer close to the substrate 100 being used.

Illustrate in FIG. 2, shows another bonding pad structure with low capacitance in the semiconductor device. The semiconductor device includes a dielectric layer 310 on the P-type substrate 300, wherein the P-type substrate 300 having a well region 304 of a second conductive type such as N-type therein, and a doped region 302 of a first conductive type such as P-type as well as a diffusion region is in the well region 304, and a bonding pad structure 400 is on the dielectric layer 310.

The bonding pad structure 400 includes a stacked metal layer and a top metal layer lies located on the P-type substrate 300 and is aligned with the P-type doped region 302. The stacked metal layer includes several metal layers for example four layers of metal, which comprises 410, 420, 430, 440, and several dielectric layer layers 412, 422, 432. Additionally, the metal layers 410, 420, 430, 440 and the dielectric layers 412, 422, 432 are stacked alternately on the P-type substrate 300. Furthermore, each of multiple metal layers adjacent to metal layer by plurality of via plugs 414, 424, 434 within the multiple di-electric layer 412, 422, and 432.

Because of the doped region 302 is inserted below the bonding pad structure 400. Thus, the bonding pad structure 400 has a much lower parasitic capacitance and the junction capacitors are inserted in serial.

In this structure as described above, a junction capacitance Cₚ occurs between the N-type well region 304 and the P-type doped region 302. A junction capacitance C_{N} occurs between the N-type well region 304 and the P-type substrate 300. The total equivalent capacitance C_{Meq} also occurs due to contribution from the metal layers 410, 420, 430, and 440. All the capacitance of Cₚ, C_{N}, and C_{Meq} are coupled in series so that a parasitic capacitance of the bonding pad structure 400 is effectively reduced.

### SUMMARY OF THE INVENTION

In accordance with the present invention, a structure is provided for forming a low capacitance bonding pad structure on the substrate, which is integrated with the triple well technology, that substantially reduce the total pad capacitance between the top metal layer and the substrate.

It is an object of this invention to provide a low-capacitance bonding pad structure for a semiconductor device to reduce the parasitic capacitance between the substrate and the top metal layer.

It is another object of this invention to integrate with a triple well technology for forming a triple well structure in the substrate of first conductive type to reduce total pad parasitic capacitance between the substrate and the top metal layer.

It is still object of this invention to provide a triple well structure in the substrate to contribute the junction capacitance that are coupled in series, such that the pad parasitic capacitance of the bonding pad structure is effectively reduced.

According to above objects, the present invention provides a low-capacitance bonding pad structure for a semi-conductor device. The semiconductor device includes a substrate, a dielectric layer on the substrate, a bonding pad structure on the substrate, and a passivation layer on the bonding pad structure. The substrate has a doped region of second conductive type as well as a diffusion region therein; a first well region of a first conductive type such as P-type is in the substrate, and is below the doped region; and a second well region of a second conductive type such as N-type is in the substrate, and is below the doped region and the first well region, wherein the first conductive type is opposite to the second conductive type. The bonding pad structure includes a multiple metal layers and a top metal layer. The multiple metal layers are constructed of plurality of metal layers and plurality of dielectric layer, wherein the plurality of metal layers buried deeply in the dielectric layer, and isolated by the dielectric layer.

Because of the first junction capacitance between the doped region of second conductive type and the first well region of first conductive type, the second junction capacitance between the first well region of the first conductive type and the second well region of the second conductive type, and the third junction capacitance between the second well region of second conductive type and the substrate that those junction capacitances are coupled in series, thus, the total pad capacitance between the substrate and top metal layer is effectively reduce, and substrate noise could be improved.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is schematic representation of structures at various stages during the formulation of the semiconductor device has a traditional RF pad structure on the substrate using conventional, prior art technique;

FIG. 2 is schematic representation of structures at various stages during the formulation of the semiconductor device has a traditional bonding pad structure on the substrate using conventional, prior art technique; and

FIG. 3 is schematic representation of structures at various stages during the formulation of a semiconductor device having a bonding pad structure integrated with triple well structure in accordance with a structure disclosed herein.

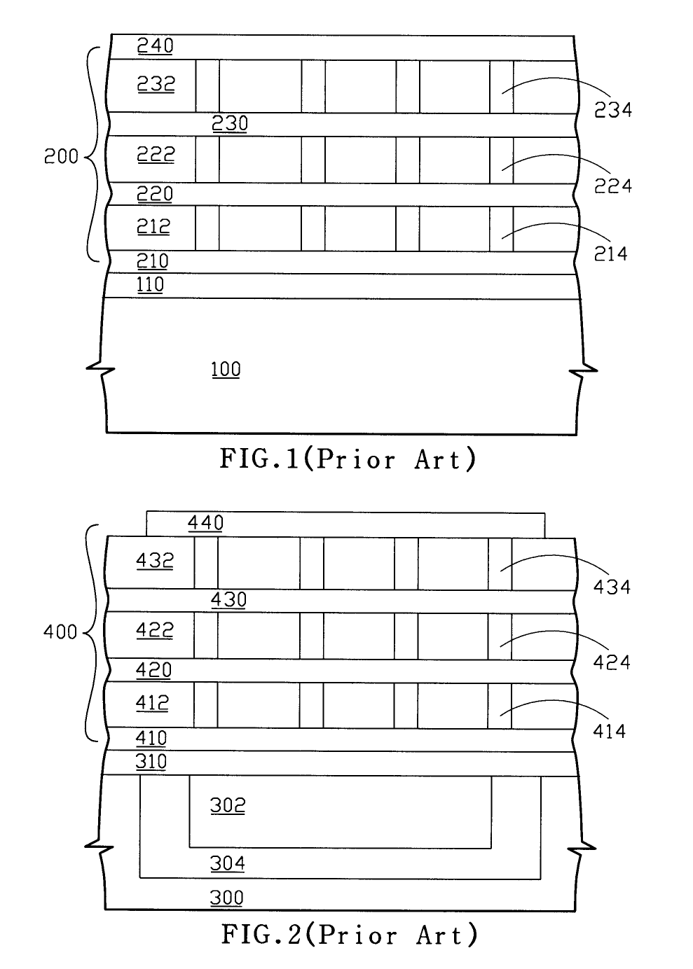

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

According to conventional bonding pad has large pad capacitance to affect the reliable of the semiconductor device, thus, the present invention provides a structure in the substrate to reduce the pad parasitic capacitance between the P-type substrate and top metal layer.

The present invention is to provide a low capacitance semiconductor device comprises a triple well structure in the substrate and a bonding pad structure on the P-type substrate, wherein the P-type substrate having a doped region of a second conductive type, a first well region of first conductive type, and a second well region of second conductive type. There is a first junction capacitance between the doped region and the first well region, a second junction capacitance between the first well region and the second well region, and a third capacitance between the second well region and the P-type substrate. The first junction capacitance, second junction capacitance, the third junction capacitance and the total equivalent capacitance is contributed by bonding pad structure are coupled in series, such that the total parasitic capacitance is effectively reduced.

Moreover, according to the preferred embodiment of the present invention, the fabrication of the bonding pad structure is integrated with the triple well CMOS (complementary metal oxide semiconductor) technology for a semiconductor device, such that the total parasitic capacitance is effectively reduced, and the substrate noise is improved.

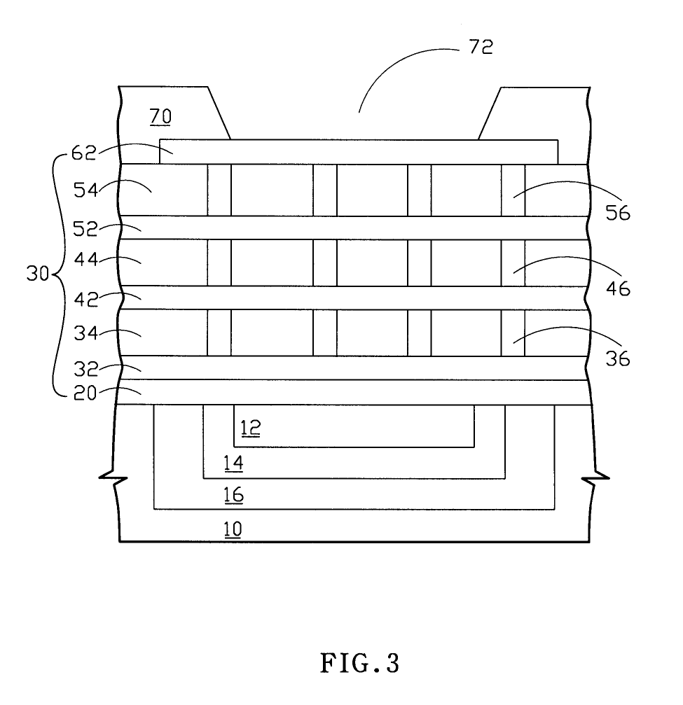

Referring FIG. 3, a semiconductor device comprises a substrate 10 of a first conductive type such as P-type, a dielectric layer 20 on the P-type substrate 10, a bonding pad structure 30 on the dielectric layer 20, and a passivation layer 70 with an pad opening 72 on the bonding pad structure 30. Using the triple well CMOS technology, the P-type substrate 10 has a first doped region 12 of a second conductive type in the P-type substrate 10. A first well region 16 of a second conductive type is in the P-type substrate 10, and is below the first doped region 12. A second well region 16 of a second conductive type, such as N-type as well as a deep well region in the P-type substrate 10, and is below the first well region 14, wherein the first conductive type is opposite to the second conductive type.

The first doped region 12 of a second conductive type is formed by conventional diffusion or ion implantation that using implanting an N-type dopant into the P-type substrate 10. The first well region 14 of a first conductive type is formed by implanting a P-type dopant such as As (Arsenic) or P (phosphorous) into the P-type substrate 10, and is below the first doped region 12. The second well region 16 of a second conductive type is formed by implanting an N-type dopant such as B (boron) into the P-type substrate 10, and is below the first doped region 12 and the first well region 14, thereby, the dopant concentration of the second well region 16 of the second conductive type is higher than the first well region 14 of the first conductive type, and the dopant concentration of the first well region 14 of the first conductive type is higher than the first doped region of the second conductive type. Therefore, there is a triple well structure in the substrate 10.

Then, a dielectric layer 20 is on the P-type substrate 10. A bonding pad structure 30 is on the dielectric layer 20. The bonding pad structure 30 comprises a multiple metal layers and a top metal layer lies located on the dielectric layer 20. The multiple metal layers include the plurality layers of the metal 32, 42, 52, 62, and the plurality layers of dielectric 34, 44, and 54. Additionally, the plurality layers of metal 32, 42, 52, 62 and the plurality layers of dielectric 34, 44, and 54 are stacked alternately on the dielectric layer 20.

In this structure as described above, a first junction capacitance C₁ occurs between the first well region 14 of first conductive type and the first doped region 12 of second conductive type. A second junction capacitance C₂ occurs between the first well region 14 of first conductive type and the second well region 16 of the second conductive type. A third junction capacitance C₃ occurs between the second well region 16 of the second conductive type and the P-type substrate 10. A total equivalent capacitance C_{Meq} also occurs due to contribute from the plurality layers of metal 32, 42, 52, and 62. Thus, the total parasitic capacitance of the semiconductor device is obtained from the first junction capacitance C₁, second junction capacitance C₂, third junction capacitance C₃, and the total equivalent capacitance C_{Meq} that are coupled in series, such that the total pad capacitance of bonding pad structure 30 is effectively reduced.

In additional, in the present invention, each of the plurality layers of the metal 32, 42, 52, and 62 are connected with the adjacent the layers of metal by via plugs 36, 46, and 56 in the plurality layers of dielectric 34, 44, 54. In the preferred embodiment, the location of the via plugs 34, 44, and 54 is not only limited to align with the adjacent the via plugs, but also to non-align with the adjacent via plugs.

Furthermore, a passivation layer 70 with a bonding pad opening 72 is formed on the top metal layer 62 that used for subsequent bonding process.

According to abovementioned, the advantages of the present invention include the following:

Firstly, the doped region of second conductive type is formed in the P-type substrate so that the contact capacitance of the doped region and the capacitance of the bonding pad structure are coupled in series. The parasitic capacitance of the bonding pad structure is reduced.

Secondly, the present invention is compatible with the triple well CMOS technology. The junction capacitance between the bonding pad structure and the P-type substrate are coupled in series, such that the total pad capacitance is effectively reduced, and the P-type substrate noise also can be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A semiconductor device integrated a triple well structure and a bonding pad structure, said semiconductor device integrated a triple well structure and a bonding pad structure comprising:
a substrate having a triple well structure therein, said triple well structure comprising a doped region of a conductive type, a first well region of a first conductive type below said doped region, and a second well region of a second conductive type below said first well region; and a bonding pad structure on said substrate.

2. The semiconductor device integrated a triple well structure and a bonding pad structure according to claim 1, wherein a dopant concentration of said second well region of said second conductive type is higher than a dopant concentration of said first well region of said first conductive type.

3. The semiconductor device integrated a triple well structure and a bonding pad structure according to claim 1, wherein said first conductive type is opposite to said second conductive type.

4. The semiconductor device integrated a triple well structure and a bonding pad structure according to claim 1, wherein said dopant concentration of said first well region of said second conductive type is higher than a dopant concentration of said doped region.

5. The semiconductor device integrated a triple well structure and a bonding pad structure according to claim 1, wherein said bonding pad structure comprises: a multiple metal layers alternating stacked with a multiple dielectric layers on said substrate; and a top metal layer on said multiple metal layers.

6. The semiconductor device integrated a triple well structure and a bonding pad structure according to claim 5, wherein said each of said multiple metal layers coupled with adjacent said each of said multiple metal layers by a plurality of via plugs in each of said multiple dielectric layers.

7. The semiconductor device integrated a triple well structure and a bonding pad structure according to claim 1, further comprising a passivation layer with a bonding pad opening on said bonding pad structure.

8. A semiconductor device with a low capacitance bonding pad structure therein, said semiconductor device with a low capacitance bonding pad structure comprising:
a substrate having a doped region of a conductive type therein;
a first well region of a first conductive type in said substrate, and below said doped region;
a second well region of a second conductive type in said substrate, and below said doped region and said first well region;
a multiple metal layers alternating with a multiple dielectric layers on said substrate, wherein said multiple metal layers are buried deeply in said multiple dielectric layers;
a top metal layer on said multiple metal layers; and
a passivation layer with an bonding pad opening therein on said top metal layer.

9. The semiconductor device with a low capacitance bonding pad structure according to claim 8, wherein said first conductive type is opposite to said second conductive type.

10. The semiconductor device with a low capacitance bonding pad structure according to claim 8, wherein a dopant concentration of said second well region of said second conductive type is higher than a dopant concentration of said first well region of said first conductive type.

11. The semiconductor device with a low capacitance bonding pad structure according to claim 8, wherein a dopant concentration of said first well region of said first conductive type is higher than a dopant concentration of said first doped region of said second conductive type.

12. The semiconductor device with a low capacitance bonding pad structure according to claim 8, wherein each of said multiple metal layers coupled with adjacent each said multiple metal layers by a plurality of via plugs in each of said multiple dielectric layers.
